(19) United States
(12) Patent Application Publication
(10) Pub. No.: US 2009/0284946 A1
(43) Pub. Date: Nov. 19, 2009

(54) FLEXIBLE PRINTED CIRCUIT FILM AND DISPLAY APPARATUS HAVING THE SAME

(75) Inventors: Jin-Wook Yang, Suwon-si (KR); Jung-ln Han, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd., Suwon-si (KR)

(21) Appl. No.: 12/025,397

(22) Filed: Feb. 4, 2008

(30) Foreign Application Priority Data
Feb. 2, 2007 (KR) 10-2007-0011183

(51) Int. Cl. H05K 9/00

(52) U.S. Cl. 361/818; 361/749

(57) ABSTRACT

A flexible printed circuit (FPC) film includes a film body portion connected to a display panel, and an electromagnetic (EM) wave blocking portion extended from the film body portion, wherein the EM wave blocking portion covers a portion of a driving chip disposed on the display panel.

### CROSS-REFERENCE TO RELATED APPLICATION

The present application claims priority under 35 U.S.C. § 119 to Korean Patent Application No. 2007-11183, filed on Feb. 2, 2007, the disclosure of which is incorporated herein by reference in its entirety.

### BACKGROUND OF THE INVENTION

1. Technical Field

The present disclosure relates to a flexible printed circuit (FPC) film and a display apparatus having the FPC film, and more particularly, to an FPC film capable of blocking an electromagnetic (EM) wave.

2. Discussion of the Related Art

A liquid crystal display (LCD) apparatus includes an LCD panel displaying an image and a backlight assembly supplying light to the LCD panel. The LCD panel includes a first substrate, a second substrate and a liquid crystal layer interposed between the first substrate and the second substrate. The backlight assembly includes a light source and a bottom chassis receiving the light source. Since the LCD apparatus is thin and light weight, and uses lower driving power and consumes less power than some other types of display devices, the LCD apparatus is used in small electronic devices, such as a mobile communication terminal, a portable multimedia player or a digital camera.

The LCD apparatus further includes a driving chip controlling the LCD panel. The driving chip is an integrated circuit element, and is disposed at a first side of the LCD panel. The driving chip operates using electric signals. The electric signals cause electromagnetic (EM) waves. To reduce the EM waves, the LCD apparatus may further include grounding tape grounding the driving chip. The grounding tape covers the driving chip and is attached to a bottom chassis comprising metal. However, manufacturing processes of the LCD apparatus including the grounding tape are complicated.

### SUMMARY OF THE INVENTION

Exemplary embodiments of the present invention provide a flexible printed circuit (FPC) film capable of blocking an electromagnetic (EM) wave and a display apparatus having the FPC film.

According to an exemplary embodiment of the present invention, a flexible printed circuit (FPC) film comprises a film body portion connected to a display panel, and an electromagnetic (EM) wave blocking portion extended from the film body portion, wherein the EM wave blocking portion covers a portion of a driving chip disposed on the display panel.

The film body portion may comprise a first insulation layer, a first conductive layer formed on the first insulation layer, and a second insulation layer formed on the first conductive layer.

The EM wave blocking portion may comprise a first covering layer extended from the first insulation layer of the film body portion, a blocking layer formed on the first covering layer and extended from the first conductive layer of the film body portion, and a second covering layer formed on the blocking layer and extended from the second insulation layer of the film body portion.

The EM wave blocking portion may further comprise an adhesion layer formed on the first covering layer.

The film body portion may further comprise a second conductive layer formed on the second insulation layer, and a third insulation layer formed on the second conductive layer.

The EM wave blocking portion can be extended from an end portion of the film body portion along a longitudinal direction of the driving chip.

The EM wave blocking portion can be extended from an uppermost layer of the film body portion by a predetermined distance.

The EM wave blocking portion may comprise a first blocking portion extended from a first end portion of the film body portion along a longitudinal direction of the driving chip, and a second blocking portion extended from a second end portion opposite the first end portion.

According to an exemplary embodiment of the present invention, a display apparatus comprises a display panel, a driving chip controlling the display panel, and an FPC film including a film body portion and an EM wave blocking portion, wherein the film body portion is connected to the display panel and the EM wave blocking portion is extended from the film body portion.

The driving chip can be disposed at a first side of the display panel, the film body portion can be bent from the first side of the display panel to a second side of the display panel, and the FPC film can be bent so that at least a part of the EM wave blocking portion covers the driving chip.

The EM wave blocking portion may comprise a first blocking portion extended from a first end portion of the film body portion along a longitudinal direction of the driving chip, and a second blocking portion extended from a second end portion opposite the first end portion.

A sum of an extended length of the first blocking portion and an extended length of the second blocking portion can be substantially the same or larger than a width of the display panel.

The display apparatus may further comprise a backlight assembly disposed behind the display panel, the backlight assembly including a light source, a light guide plate disposed at a first side of the light source, a mold frame guiding the light source and the light guide plate and supporting the display panel, and a bottom chassis combined with the mold frame to receive the light source and the light guide plate.

The EM wave blocking portion can be disposed adjacent a first side of the mold frame.

The EM wave blocking portion can be disposed adjacent a first side of the bottom chassis or a rear side of the bottom chassis.

The film body portion and the EM wave blocking portion can be spaced apart form each other on the display panel.

The EM wave blocking portion can cover a first side of the display panel.

The driving chip can be disposed on the film body portion, and the EM wave blocking portion may include a first blocking portion bent from a first end portion of the film body portion along a longitudinal direction of the driving chip toward the driving chip.

The EM wave blocking portion may further comprise a second blocking portion extended from a second end portion of the film body portion opposite the first end portion of the film body portion.

The first blocking portion and the second blocking portion can be formed along the same line as the driving chip is formed.

### BRIEF DESCRIPTION OF THE DRAWINGS

Exemplary embodiments of the present invention can be understood in more detail from the following descriptions taken in conjunction with the accompanying drawings, in which:

FIG. 1 is an exploded perspective view showing a display apparatus according to an exemplary embodiment of the present invention;

FIG. 2 is a plan view showing a display panel, a driving chip and a flexible printed circuit (FPC) film, according to an exemplary embodiment of the present invention;

FIG. 3 is a cross-sectional view taken along the line I-I′ shown in FIG. 2, according to an exemplary embodiment of the present invention;

FIG. 4 is a cross-sectional view taken along the line I-I′ shown in FIG. 2, according to an exemplary embodiment of the present invention;

FIG. 5 is a cross-sectional view taken along the line I-I′ shown in FIG. 2, according to an exemplary embodiment of the present invention;

FIG. 6 is a plan view showing bent FPC film, according to an exemplary embodiment of the present invention;

FIG. 7 is a cross-sectional view taken along the line II-II shown in FIG. 6;

FIG. 8 is an enlarged view showing the portion ‘A’ shown in FIG. 7;

FIG. 9 is a cross-sectional view taken along the line III-III shown in FIG. 6;

FIG. 10 is a cross-sectional view taken along the same direction as the line II-II′ shown in FIG. 6, according to an exemplary embodiment of the present invention;

FIG. 11 is a cross-sectional view showing the display apparatus shown in FIG. 10 taken along the same direction as the line III-III′ shown in FIG. 6;

FIG. 12 is a plan view showing an FPC film according to an exemplary embodiment of the present invention;

FIG. 13 is a plan view showing a display apparatus, according to an exemplary embodiment of the present invention;

FIG. 14 is a plan view showing an FPC film and a driving chip, according to an exemplary embodiment of the present invention;

FIG. 15 is a cross-sectional view taken along the line IV-IV′ shown in FIG. 14;

FIG. 16 is an enlarged view showing the portion ‘B’ shown in FIG. 15; and

FIG. 17 is a cross-sectional view showing a bent FPC film, according to an exemplary embodiment of the present invention.

### DESCRIPTION OF EXEMPLARY EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein.

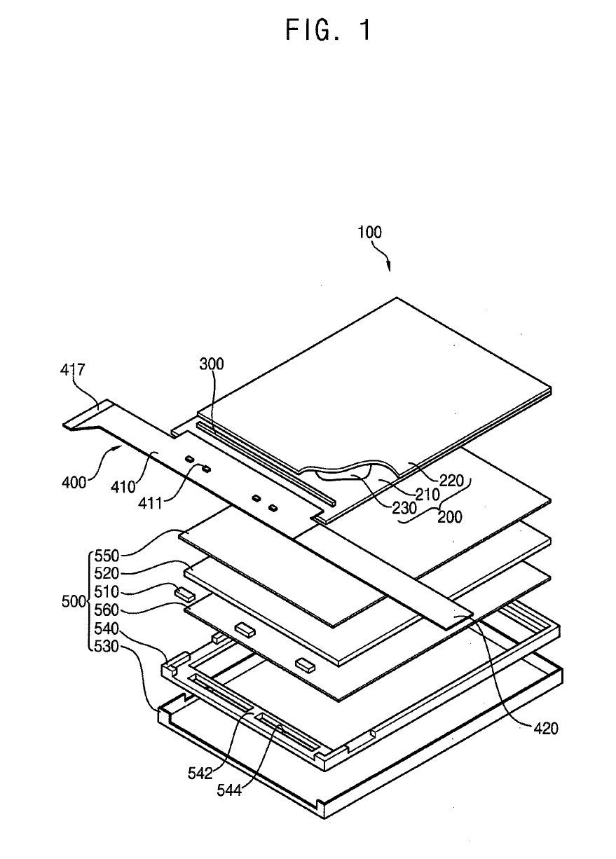

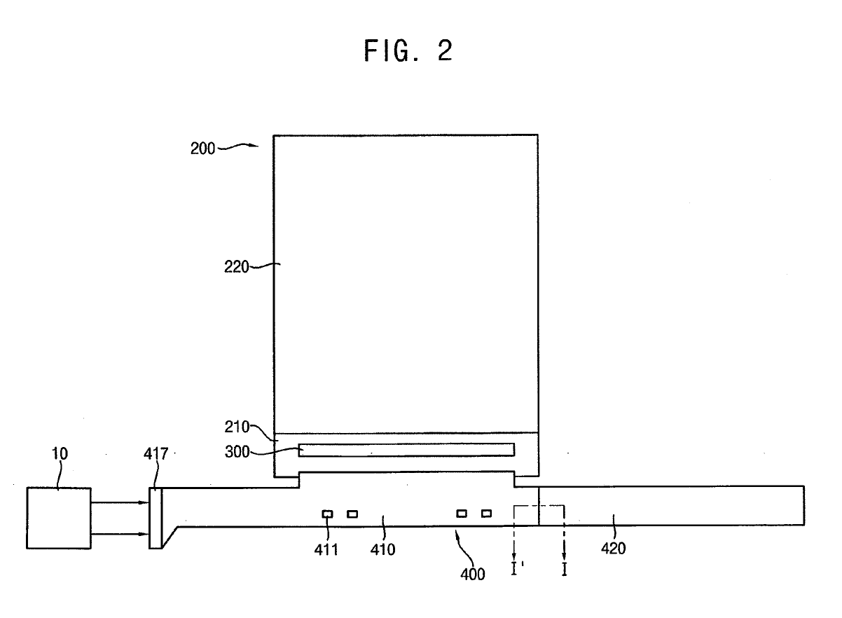

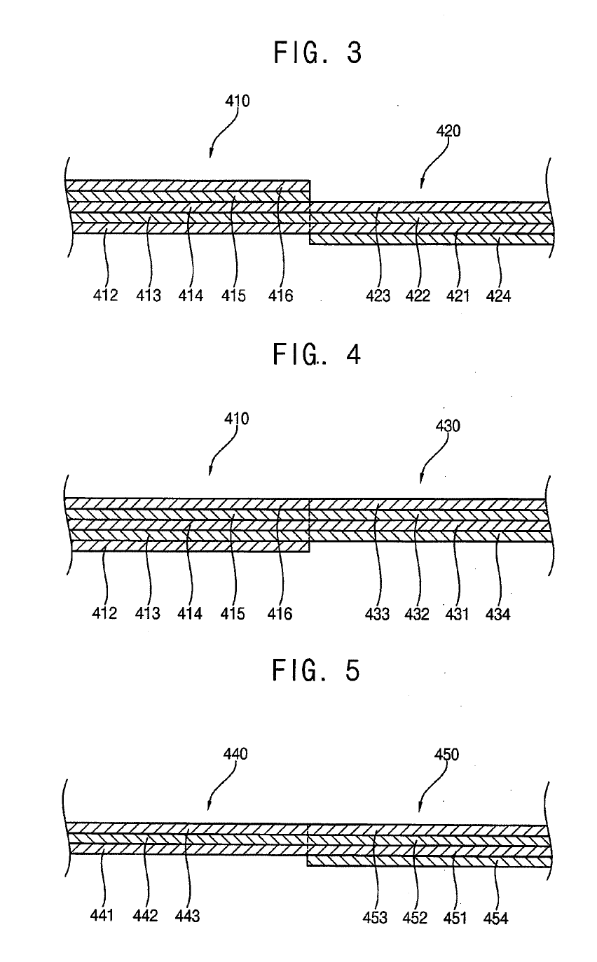

FIG. 1 is an exploded perspective view showing a display apparatus according to an exemplary embodiment of the present invention. FIG. 2 is a plan view showing a display panel, a driving chip and a flexible printed circuit (FPC) film according to an exemplary embodiment of the present invention. FIG. 3 is a cross-sectional view taken along the line I-I′ shown in FIG. 2 according to an exemplary embodiment of the present invention.

Referring to FIGS. 1 to 3, a display apparatus 100 includes a display panel 200, a driving chip 300 and a flexible printed circuit (FPC) film 400.

The display panel 200 displays an image. The display panel 200 includes a first substrate 210 and a second substrate 220 facing the first substrate 210. The first substrate 210 may be a thin film transistor (TFT) substrate including a TFT formed in a matrix. The TFT acts as a switching element. The second substrate 220 may be a color filter substrate including, for example, a red color, a blue color and a green color.

The display panel 200 may further include a liquid crystal layer 230 interposed between the first substrate 210 and the second substrate 220. The liquid crystal layer 230 includes a plurality of liquid crystal molecules (not shown). The display panel 200 can display an image by adjusting light passing through the liquid crystal molecules. The light is supplied from a backlight assembly 500 disposed behind the display panel 200.

In an exemplary embodiment, the display panel 200 may include an organic light emitting layer interposed between the first substrate 210 and the second substrate 220. The organic light emitting layer may generate white light mixed by red light, green light and blue light. In an exemplary embodiment, the organic light emitting layer may sequentially emit red light, green light and blue light according to positions of each light source.

The driving chip 300 is positioned on the display panel 200. In an exemplary embodiment, the driving chip 300 is positioned at a first side of the first substrate 210. The first substrate 210, including the first side where the driving chip 300 is disposed, may have a size greater than the size of a second substrate 220.

The driving chip 300 controls the display panel 200. The driving chip 300 receives a driving signal applied from an external controller 10, and generates a control signal. The control signal is applied to the first substrate 210 and the second substrate 220. The driving signal may be applied through the FPC film 400.

The driving chip 300 is an electronic element. In an exemplary embodiment, the driving chip 300 may be an integrated circuit element. The driving chip 300 may include a semiconductor material.

Since the electronic elements are operated by an external electrical signal, the electronic elements can generate an electromagnetic (EM) wave. Thus, the driving chip 300 may generate the EM wave.

The EM wave may affect the first substrate 210 and the second substrate 220. Thus, the EM wave may cause a display malfunction of the display panel 200.

The FPC film 400 includes a film body portion 410 and an EM wave blocking portion 420. The film body portion 410 is electrically connected to the display panel 200. In an exemplary embodiment, the film body portion 410 is attached at the first side of the first substrate 210 where the driving chip 300 is disposed. The film body portion 410 is electrically connected to the controller 10. The film body portion 410 receives the driving signal from the controller 10, and applies the driving signal to the driving chip 300. The film body portion 410 may include a plurality of driving elements 411 to apply the driving signal. The driving elements 411 may include, for example, a resistor, a capacitor or a diode.

The film body portion 410 includes a first insulation layer 412, a first conductive layer 413 and a second insulation layer 414. When the film body portion 410 is bent toward a rear side of the display panel 200, the first insulation layer 412 is disposed opposite the rear side of the display panel 200.

The first conductive layer 413 is formed on the first insulation layer 412. The first conductive layer 413 applies the driving signal to the driving chip 300. The first conductive layer 413 is electrically connected to an external grounding portion (not shown). The second insulation layer 414 is formed on the first conductive layer 413.

The film body portion 410 may further include a second conductive layer 415 and a third insulation layer 416. The second conductive layer 415 is formed on the second insulation layer 414. The second conductive layer 415 acts as an auxiliary layer of the first conductive layer 413. In an exemplary embodiment, the driving elements 411 may be disposed on the first conductive layer 413. Driving lines applying the driving signal and grounding lines may be disposed on the second conductive layer 415. The third insulation layer 416 is formed on the second conductive layer 415.

The film body portion 410 includes a multilayer structure having the first insulation layer 412, the first conductive layer 413, the second insulation layer 414, the second conductive layer 415 and the third insulation layer 416 which are formed sequentially. The film body portion 410 having a multilayer structure may be referred to as a double layer film. When the film body portion 410 includes one of the first and second conductive layers 413, 415, the film body portion 410 may be referred to as a single layer film.

The EM wave blocking portion 420 extends from the film body portion 410. The EM wave blocking portion 420 extends from a first end portion of the film body portion 410 along a longitudinal direction of the driving chip 300.

In an exemplary embodiment, the EM wave blocking portion 420 is spaced apart from an uppermost layer of the film body portion 410 by a predetermined distance. According to an embodiment, when the film body portion 410 is bent toward a rear side of the display panel 200, the film body portion 410 does not interfere with the first substrate 210.

The film body portion 410 may include a connecting pad portion 417 electrically connected to the external controller 10 and formed at a second end portion formed opposite the first end portion where the EM wave blocking portion 420 is connected.

The EM wave blocking portion 420 covers the driving chip 300 to electrically protect the driving chip 300 from the EM waves. The EM wave blocking portion 420 blocks an EM wave generated from the driving chip 300. The EM wave blocking portion 420 includes a first covering layer 421, a blocking layer 422 and a second covering layer 423. The first covering layer 421 faces the driving chip 300. The first covering layer 421 extends from the first insulation layer 412 of the film body portion 410.

The blocking layer 422 extends from the first conductive layer 413. The blocking layer 422 blocks the EM wave generated from the driving chip 300. To block the EM wave, the first conductive layer 413 may include a grounding line (not shown) connected to an external grounding portion (not shown) and electrically connected to the blocking layer 422.

The grounding portion may be electrically connected to an external metal case to maximize an area of the grounding portion. The grounding portion may be electrically connected to a bottom chassis 530 of the backlight assembly 500 positioned behind the display panel 200. The second covering layer 423 is formed on the blocking layer 422. The second covering layer 423 extends from the second insulation layer 414.

The first covering layer 421, the blocking layer 422 and the second covering layer 423 of the EM wave blocking portion 420 extend from the first insulation layer 412, the first conductive layer 413 and the first insulation layer 412 of the film body portion 410, respectively.

The EM wave is transferred to an outside through the EM wave blocking portion 420 and the film body portion 410 so that the EM wave can be reduced. The EM wave is transferred to the external grounding portion through the grounding line formed on the second conductive layer 415 of the FPC film 400. In an exemplary embodiment, the EM wave may be reflected by the blocking layer 422 so that the EM wave may be prevented from being leaked to the outside.

The EM wave blocking portion 420 may further include an adhesion layer 424 formed on the first covering layer 421 to cover the driving chip 300. In an exemplary embodiment, the adhesion layer 424 may include, for example, a double sided adhesion tape. When the film body is attached to a rear side of the backlight assembly 500, the adhesion layer 424 may extend on the first insulation layer 412.

According to an exemplary embodiment of the present invention, the FPC film 400 includes the EM wave blocking portion 420 to block the EM wave generated from the driving chip 300 so that grounding tape can be removed. Thus, the EM wave may be blocked. A process blocking the EM wave generated from the driving chip 300 can be simplified. Manufacturing costs can be reduced by removing the grounding tape. An additional thickness of the display apparatus caused by the grounding tape can be prevented.

The blocking layer 422 of the EM wave blocking portion 420 may include, for example, metal having a reflective property. Thus, the EM wave blocking portion 420 blocks external light incident to the driving chip 300. When the external light is incident to a channel layer (not shown) formed in the driving chip 300 or on the first substrate 210, driving malfunction can occur. Since the channel layer includes a semiconductor material, the quality of the channel layer affected by the external light can be deteriorated.

The display apparatus 100 may further include the backlight assembly 500 facing a side of the display panel 200 to provide light with the display panel 200. In an exemplary embodiment, the backlight assembly 500 may be positioned behind the display panel 200.

The backlight assembly 500 may include a light source 510, a light guide plate 520, the bottom chassis 530, a mold frame 540, an optical sheet 550 and a reflective sheet 560. The light guide plate 520 guides light generated from the light source 510 toward the display panel 200. The bottom chassis 530 receives the light guide plate 520 and the light source 510. The mold frame 540 guides the light guide plate 520, and supports the display panel 200. The mold frame 540 is combined with an inner side of the bottom chassis 530. The optical sheet 550 is disposed between the first substrate 210 and the light guide plate 520 to improve light characteristics emitted from the light guide plate 520. The reflective sheet 560 is disposed between the light guide plate 520 and the bottom chassis 530 to reflect the light leaking from the light guide plate 520. The light source 510 may include a light emitting diode.

FIG. 4 is a cross-sectional view taken along the line I-I′ shown in FIG. 2 according to an exemplary embodiment of the present invention.

Referring to FIGS. 2 and 4, the EM wave blocking portion 430 includes the first covering layer 431 extending from the second insulation layer 414, the blocking layer 432 extending from the second conductive layer 415 and the second covering layer 433 extending from the third insulation layer 416.

When the film body portion 410 is bent toward a rear side of the display panel 200, the EM wave blocking portion 430 may extend from an outer side of the rear side of the display panel 200. The EM wave blocking portion 430 may include the first conductive layer 413 and the first insulation layer 412 of the film body portion 410 disposed between the EM wave blocking portion 430 and the rear side of the display panel 200.

The EM wave blocking portion 430 includes an adhesion layer 434 formed on the first covering film 431 to cover the driving chip 300. When the film body portion 410 is attached to the rear side of the backlight assembly 500, the adhesion layer 434 may extend toward an upper side of the first insulation layer 412. Since the thin film body portion 410 and surfaces of the EM wave blocking portion 430 where the adhesion layer 434 is formed include a stepped portion, the adhesion layer 434 may be incised at a border between the film body portion and the EM wave blocking portion 430. Thus, the EM wave blocking portion 430 can be bent by using the incision.

In an exemplary embodiment, the EM wave blocking portion 430 may use the second conductive layer 415 as a blocking layer.

FIG. 5 is a cross-sectional view taken along the line I-I′ shown in FIG. 2 according to an exemplary embodiment of the present invention.

Referring to FIGS. 2 and 5, the film body portion 440 includes a first insulation layer 441, a conductive layer 442 and a second insulation layer 443.

In an exemplary embodiment, the film body portion 440 includes a conductive layer 442. When the film body portion 440 includes a single conductive layer 442, the film body portion 440 may be referred to as a single layer film. In an exemplary embodiment, an EM wave blocking portion 450 may include a first covering layer 451 extending from the first insulation layer 441, a blocking layer 452 extending from the conductive layer 442, and a second covering layer 453 extending from the second insulation layer 443. The EM wave blocking portion 450 may further include an adhesion layer 454 formed opposite the blocking layer 452 with respect to the first covering layer 451 therebetween.

In an exemplary embodiment, the film body portion 440 having the single layer film may form the EM wave blocking portion 450.

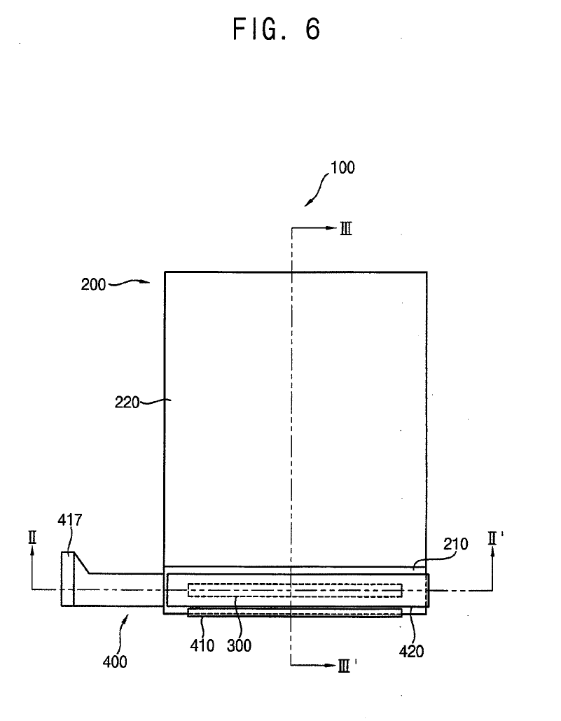

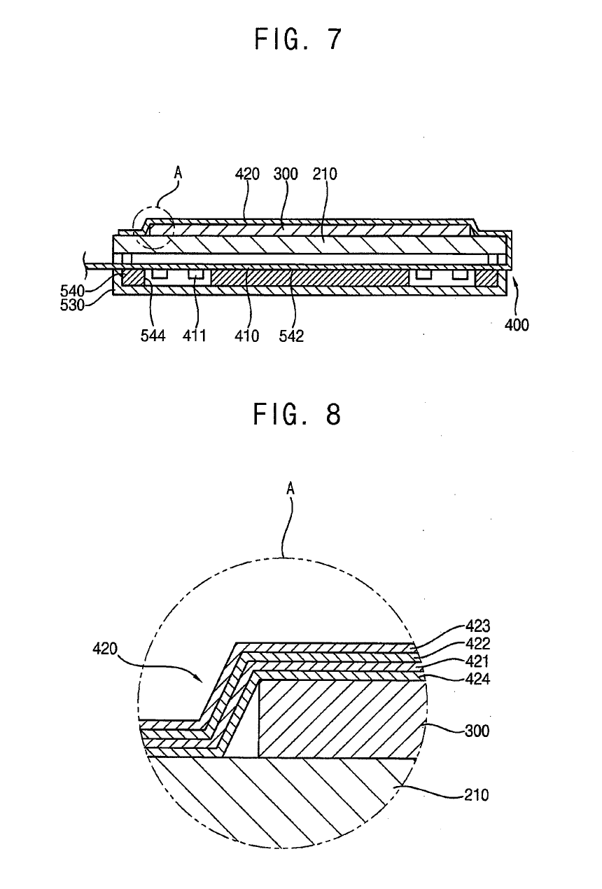

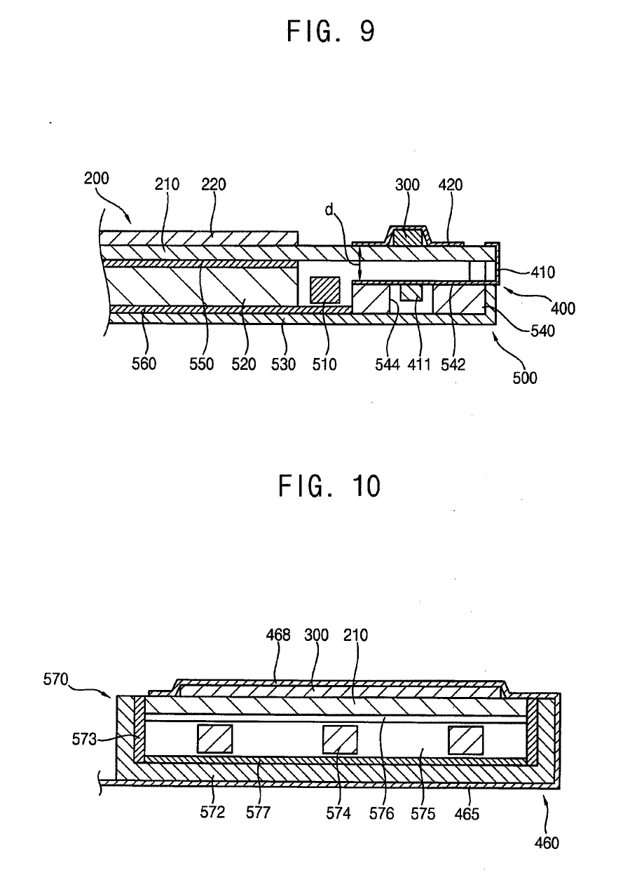

FIG. 6 is a plan view showing a bent FPC film according to an exemplary embodiment of the present invention. FIG. 7 is a cross-sectional view taken along the line II-II′ shown in FIG. 6. FIG. 8 is an enlarged view showing the portion ‘A’ shown in FIG. 7. FIG. 9 is a cross-sectional view taken along the line III-III′ shown in FIG. 6.

Referring to FIGS. 6 to 9, the film body portion 410 of the FPC film 400 is bent toward an opposing side of the driving chip 300 of the display panel 200. The driving chip 300 is disposed on the first substrate 210 of the display panel 200, and the film body portion 410 is positioned behind the display panel 200.

When the film body portion 410 is bent, the EM wave blocking portion 420 is bent toward the driving chip 300 thereon to cover the driving chip 300. The EM wave blocking portion 420 includes the driving chip 300 by using the adhesion layer 424, and is attached to the first substrate 210 of the display panel 200.

In an exemplary embodiment, the adhesion layer 424 is formed at an edge of the first covering layer 421 of the EM wave blocking portion 420. Thus, the EM wave blocking portion 420 may be attached to the first substrate 210 only.

The driving elements 411 are positioned at a side of the film body portion 410 opposite the rear side of the display panel 200. The film body portion 410 is inserted into the mold frame 540. The mold frame 540 includes a receiving portion 542 to receive the film body portion 410. The EM wave blocking portion 420 is guided by the receiving portion 542 so that the EM wave blocking portion 420 is bent toward the driving chip 300.

The receiving portion 542 includes an opening portion 544 to receive the driving elements 411. In an exemplary embodiment, the film body portion 410 is fixed to the receiving portion 542 to prevent the EM blocking portion 420 from being dislocated. An adhesion tape may be disposed between the film body portion 410 and the receiving portion 542.

The film body portion 410 applies the driving signal to the driving chip 300 and blocks EM waves which are generated from the driving chip 300 and are transmitted through the first substrate 210. The EM waves generated from the driving chip 300 can be blocked by the FPC film 400.

In an exemplary embodiment, the EM wave blocking portion 420 is spaced apart from the film body portion 410 on the first substrate 210 by a predetermined distance d. The blocking layer 422 of the EM wave blocking portion 420 may be prevented from interfering one of the first conductive layer 413 and the second conductive layer 415. In an exemplary embodiment, the film body portion 410 and the EM wave blocking portion 420 may overlap each other on the first substrate 210 by a predetermined distance. The adhesion layer 424 and the first covering layer 421 of the EM blocking portion 420 function as an insulator.

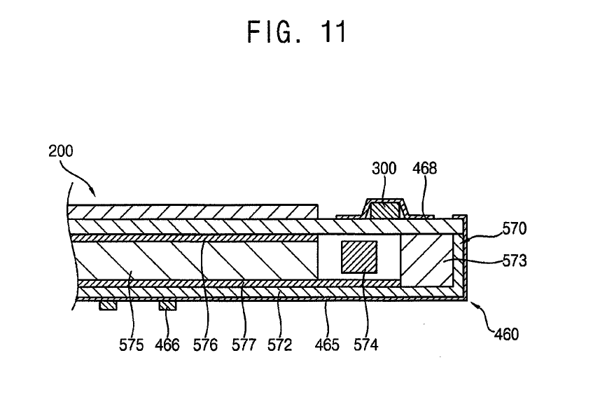

FIG. 10 is a cross-sectional view taken along the same direction as the line II-II′ shown in FIG. 1 according to an exemplary embodiment of the present invention. FIG. 11 is a cross-sectional view showing the display apparatus shown in FIG. 10 taken along the same direction as the line shown in FIG. 6.

Referring to FIGS. 1, 10 and 11, a film body portion 465 of an FPC film 460 is bent toward a rear side of a backlight assembly 570 to be attached to the rear side of the backlight assembly 570.

In an exemplary embodiment, the film body portion 465 of the FPC film 460 is attached to a rear side of a bottom chassis 572. The adhesion layer 424 of FIG. 3 of the EM wave blocking portion 468 may extend to the film body portion 465. In an exemplary embodiment, the adhesion tape is disposed between the film body portion 465 and the rear side of the bottom chassis 572. Thus, the EM wave blocking portion 468 is bent to the driving chip 300 along an outer side including the rear side of the bottom chassis 572.

The driving elements 466 of the film body portion 465 are disposed opposite the rear side of the bottom chassis 572 of the film body portion 465. This configuration prevents an attachment of the film body 465 from interfering with the driving elements 466. In an exemplary embodiment, the driving elements 466 are disposed at a side facing the rear side of the bottom chassis 572. The rear side of the bottom chassis 572 may include an exposing portion exposing the driving elements 466.

When the FPC film 460 extends to the rear side of the backlight assembly 570 to be attached, the FPC film 460 includes the EM wave blocking portion 468 so that a process for blocking the EM wave generated from the driving chip 300 formed on the first substrate 210 may be simplified.

The backlight assembly 570 includes a mold frame 573, a light source 574, a light guide plate 575, an optical sheet 576 and a reflective sheet 577. The mold frame 573 is combined with an inner side of the bottom chassis 572. The bottom chassis 572 receives the light source 574. The light guide plate 575 is disposed a first side of the light source 574. The optical sheet 576 is disposed between the light guide plate 575 and the display panel 200. The reflective sheet 577 is disposed opposite the optical sheet 576.

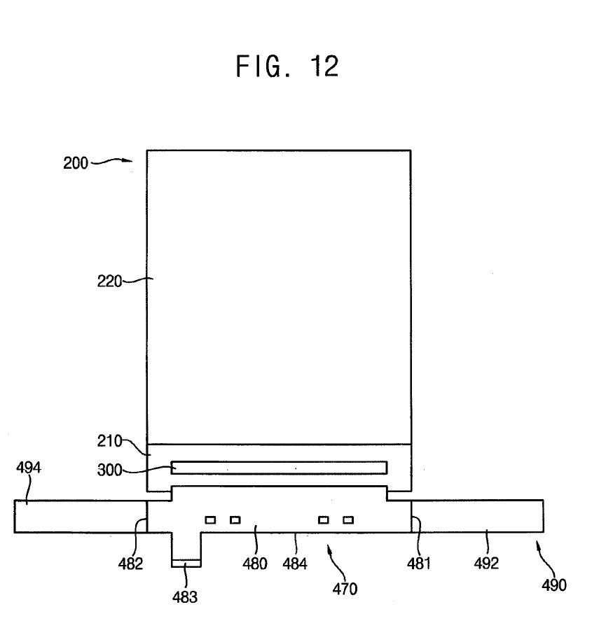

FIG. 12 is a plan view showing an FPC film according to an exemplary embodiment of the present invention.

Referring to FIGS. 1 and 12, an EM wave blocking portion 490 of the FPC film 470 includes a first blocking portion 492 and a second blocking portion 494.

The first blocking portion 492 is bent from a first end portion 481 of the film body portion 480 to the driving chip 300 along a longitudinal direction of the driving chip 300. The second blocking portion 494 is bent from a second end portion 482 opposite the first end portion 481 to the driving chip 300.

The EM wave blocking portion 490 is formed at the first and second end portions 481 and 482 of the film body portion 480 along the longitudinal direction of the driving chip 300. In an exemplary embodiment, a connecting pad portion 483 of the film body portion 480 is formed at a third end portion 484 along a perpendicular direction to the longitudinal direction of the driving chip 300.

The sum of the extended lengths of the first and second blocking portions 492 and 494 may be substantially the same as the width of the first substrate 210 of the display panel 200 where the driving chip 300 is disposed. Manufacturing costs can be reduced by minimizing an area where the first and second blocking portions 492 and 494 are formed. In an exemplary embodiment, the sum of the lengths of the first and second blocking portions 492 and 494 may be larger than the width of the first substrate 210 of the display panel 200 where the driving chip 300 is disposed.

The EM wave blocking portion 490 includes the first blocking portion 492 and the second blocking portion 494 which cover each half of the driving chip 300, respectively. Thus, the first and second blocking portions 492 and 494 can be attached to cover the driving chip 300.

Each length of the first and second blocking portions 492 and 494 may be formed to be substantially half compared to the length of the EM wave blocking portion 490 formed at one of the first and second end portions 481 and 482. The first and second blocking portions 492 and 494 may be accurately attached.

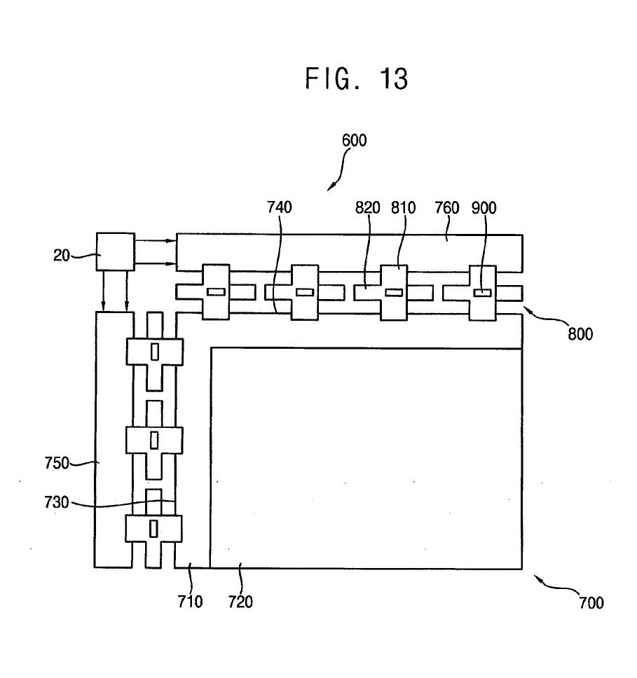

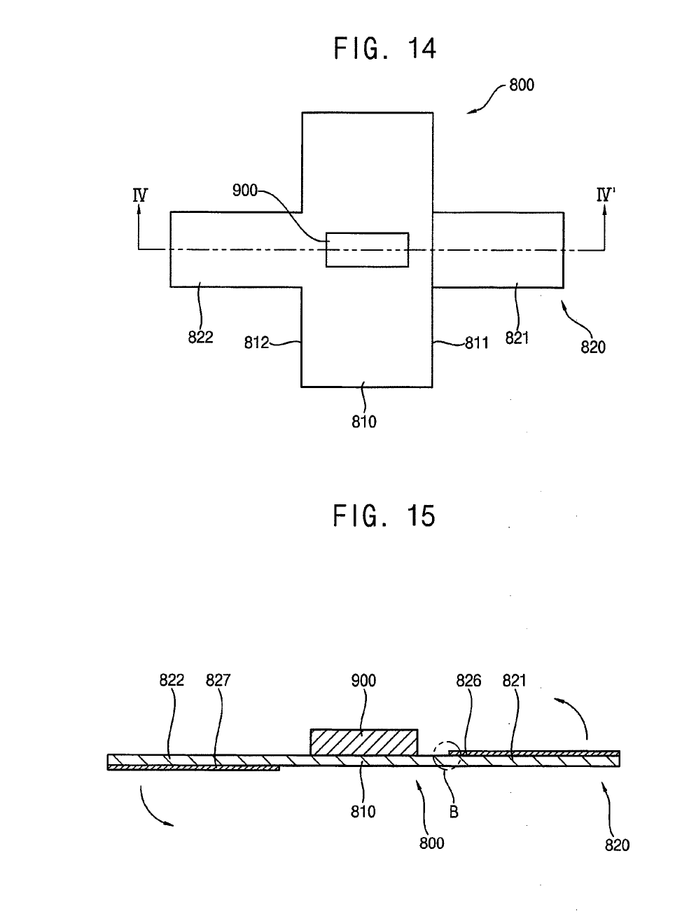

FIG. 13 is a plan view showing a display apparatus according to an exemplary embodiment of the present invention. FIG. 14 is a plan view showing an FPC film and a driving chip according to an exemplary embodiment of the present invention.

Referring to FIGS. 13 and 14, a display apparatus 600 according to an exemplary embodiment of the present invention includes a display panel 700, an FPC film 800 and a driving chip 900.

The display panel 700 includes a first substrate 710 and a second substrate 720. The first substrate 710 may be larger than the second substrate 720 such that at least one side portion of the display panel 700 extends beyond the second substrate 720. In an exemplary embodiment, the first substrate 710 can extend at first and second side portions 730 and 740. When a size of the display apparatus 600 becomes bigger, the driving signal may be divided into gate and data signals.

The first side portion 730 and the second side portion 740 of the display panel 700 are electrically connected to a gate driving circuit substrate 750 and a data driving circuit substrate 760 through the FPC film 800, respectively. The gate driving circuit substrate 750 and the data driving circuit substrate 760 are connected to an external controller 20. The gate driving circuit substrate 750 and the data driving circuit substrate 760 include a grounding line (not shown) connected to an external grounding portion (not shown) through the external controller 20.

The FPC film 800 includes a film body portion 810 connecting the display panel 700 with the gate driving circuit substrate 750 and the data driving circuit substrate 760.

The driving chip 900 is disposed on the film body portion 810. The driving chip 900 is disposed along a substantially perpendicular direction to a connecting direction of the film body portion 810. Since the driving chip 900 is an integrated circuit element, the driving chip 900 can generate an EM wave.

The FPC film 800 may further include an EM wave blocking portion 820 blocking the EM wave. The EM wave blocking portion 820 extends from the film body portion 810 to cover the driving chip 900.

The EM wave blocking portion 820 includes a first blocking portion 821. The first blocking portion 821 is formed extending from a first end portion 811 of the film body portion 810 along a longitudinal direction of the driving chip 900. In an exemplary embodiment, the width of the first blocking portion 821 is larger than that of the driving chip 900. The first blocking portion 821 is formed on along the substantially same line as the driving chip 900 is formed. Thus, the first blocking portion 821 can cover the driving chip 900 with a minimum area.

In an exemplary embodiment, the EM wave blocking portion 820 includes a second blocking portion 822 extending from a second end portion 812 opposite the first end portion 811 of the film body portion 810. The second blocking portion 822 and the first blocking portion 821 are formed along the same horizontal line. The second blocking portion 822 and the first blocking portion 821 are formed along the same line as the driving chip 900 is formed. The FPC film 800 may have a cross shape.

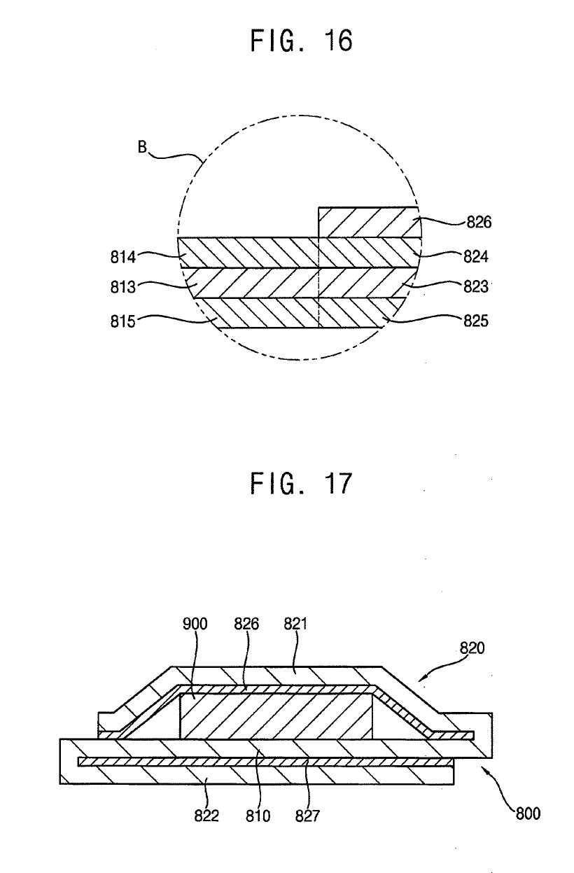

FIG. 15 is a cross-sectional view taken along the line IV-IV′ shown in FIG. 14. FIG. 16 is an enlarged view showing the portion ‘B’ shown in FIG. 15. FIG. 17 is a cross-sectional view showing a bent FPC film according to an exemplary embodiment of the present invention.

Referring to FIGS. 15 to 17, the first blocking portion 821 of the EM wave blocking portion 820 is bent to a first side of the driving chip 900. The second blocking portion 822 is bent to a second side of the film body portion 810. The first side and the second side are formed opposite each other.

In an exemplary embodiment, the first and second blocking portions 821 and 822 are bent opposite each other. The first and second blocking portions 821 and 822 cover the driving chip 900 so that the EM wave generated from the driving chip 900 can be blocked.

In an exemplary embodiment, the film body portion 810 overlaps the second blocking portion 822. Thus, the EM wave blocking portion 820 includes only the first blocking portion 821 covering an exposed portion of the driving chip 900.

When the size of the display apparatus 600 becomes larger, the film body portion 810 may include a single layer film. In an exemplary embodiment, the film body portion 810 includes a conductive layer 813 and first and second insulation layers 814 and 815 formed on both sides of the conductive layer 813. A plurality of conductive lines including a driving line and a grounding line are formed on the conductive layer 813. In an exemplary embodiment, the film body portion 810 includes a double layer film having different conductive layers.

The EM wave blocking portion 820 includes a blocking layer 823 extending from the conductive layer 813, a first covering layer 824 extending from the first insulation layer 814 and a second covering layer 825 extending from the second insulation layer 815. The conductive layer 813 may be electrically connected to the grounding line of the gate driving circuit substrate 750 or the data driving circuit substrate 760. When the film body portion 810 includes the double layer film, the EM wave blocking portion 820 may be formed from another conductive layer.

The EM wave blocking portion 820 may further include a first adhesion layer 826 and a second adhesion layer 827. The first adhesion layer 826 is formed on a surface of the first covering layer 824 opposite the conductive layer 813. In an exemplary embodiment, the first blocking portion 821 is attached to the film body portion 810 by the first adhesion layer 826.

The second adhesion layer 827 is formed on a side of the second covering layer 825 opposite the conductive layer 813. In an exemplary embodiment, the second blocking portion 822 is attached to the film body portion 810 by the second adhesion layer 827.

Since the EM wave blocking portion 820 of the FPC film 800 is attached to the film body portion 810 to surround the driving chip 900, the EM wave generated from the driving chip 900 can be blocked.

According to an exemplary embodiment of the present invention, EM waves generated from a driving chip can be blocked by using an EM wave blocking portion of an FPC film connected to a display panel.

A conventional grounding tape can be removed so that manufacturing costs can be decreased, and the thickness of the display panel can be reduced.

Although the illustrative embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. A flexible printed circuit (FPC) film comprising:
a film body portion connected to a display panel; and
an electromagnetic (EM) wave blocking portion extended from the film body portion,
wherein the EM wave blocking portion covers a portion of a driving chip disposed on the display panel.

2. The FPC film of claim 1, wherein the film body portion comprises:
a first insulation layer;
a first conductive layer formed on the first insulation layer; and
a second insulation layer formed on the first conductive layer.

3. The FPC film of claim 2, wherein the EM wave blocking portion comprises:
a first covering layer extended from the first insulation layer of the film body portion;
a blocking layer formed on the first covering layer and extended from the first conductive layer of the film body portion; and
a second covering layer formed on the blocking layer and extended from the second insulation layer of the film body portion.

4. The FPC film of claim 3, wherein the EM wave blocking portion further comprises an adhesion layer formed on the first covering layer.

5. The FPC film of claim 2, wherein the film body portion further comprises:
a second conductive layer formed on the second insulation layer; and
a third insulation layer formed on the second conductive layer.

6. The FPC film of claim 1, wherein the EM wave blocking portion is extended from an end portion of the film body portion along a longitudinal direction of the driving chip.

7. The FPC film of claim 1, wherein the EM wave blocking portion is extended from an uppermost layer of the film body portion by a predetermined distance.

8. The FPC film of claim 1, wherein the EM wave blocking portion comprises:
a first blocking portion extended from a first end portion of the film body portion along a longitudinal direction of the driving chip; and
a second blocking portion extended from a second end portion opposite the first end portion.

9. A display apparatus comprising:
a display panel;
a driving chip controlling the display panel; and
an FPC film including a film body portion and an EM wave blocking portion,
wherein the film body portion is connected to the display panel and the EM wave blocking portion is extended from the film body portion.

10. The display apparatus of claim 9, wherein the driving chip is disposed at a first side of the display panel, the film body portion is bent from the first side of the display panel to a second side of the display panel, and the FPC film is bent so that at least a part of the EM wave blocking portion covers the driving chip.

11. The display apparatus of claim 10, wherein the EM wave blocking portion comprises:
a first blocking portion extended from a first end portion of the film body portion along a longitudinal direction of the driving chip; and
a second blocking portion extended from a second end portion opposite the first end portion.

12. The display apparatus of claim 11, wherein a sum of an extended length of the first blocking portion and an extended length of the second blocking portion is substantially the same or larger than a width of the display panel.

13. The display apparatus of claim 10, further comprising a backlight assembly disposed behind the display panel, the backlight assembly including:
a light source;
a light guide plate disposed at a first side of the light source;
a mold frame guiding the light source and the light guide plate and supporting the display panel; and
a bottom chassis combined with the mold frame to receive the light source and the light guide plate.

14. The display apparatus of claim 13, wherein the EM wave blocking portion is disposed adjacent a first side of the mold frame.

15. The display apparatus of claim 13, wherein the EM wave blocking portion is disposed adjacent a first side of the bottom chassis or a rear side of the bottom chassis.

16. The display apparatus of claim 9, wherein the film body portion and the EM wave blocking portion are spaced apart form each other on the display panel.

17. The display apparatus of claim 9, wherein the EM wave blocking portion covers a first side of the display panel.

18. The display apparatus of claim 9, wherein the driving chip is disposed on the film body portion, and the EM wave blocking portion includes a first blocking portion bent from a first end portion of the film body portion along a longitudinal direction of the driving chip toward the driving chip.

19. The display apparatus of claim 18, wherein the EM wave blocking portion further comprises a second blocking portion extended from a second end portion of the film body portion opposite the first end portion of the film body portion.

20. The display apparatus of claim 19, wherein the first blocking portion and the second blocking portion are formed along the same line as the driving chip is formed.
